(19) United States
(12) Patent Application Publication
(10) Pub. No.: US 2026/0143953 A1
(43) Pub. Date: May 21, 2026

(54) DISPLAY DEVICE, ELECTRONIC DEVICE, AND MANUFACTURING METHOD OF DISPLAY DEVICE

(71) Applicant: SAMSUNG DISPLAY CO., LTD., YONGIN-SI (KR)

(72) Inventors: Hee Kyun SHIN, Yongin-si (KR); Yong-Hoon YANG, Yongin-si (KR); Yung Bin CHUNG, Yongin-si (KR)

(21) Appl. No.: 19/333,857

(22) Filed: Sep. 19, 2025

(30) Foreign Application Priority Data
Nov. 20, 2024 (KR) 10-2024-0166226

(51) Int. Cl. H10K 59/80; H10K 59/12

(52) U.S. Cl. CPC H10K 59/873; H10K 59/1201

(57) ABSTRACT

A display device includes a substrate including a pixel region and a transmission region. A transistor is disposed on the pixel region of the substrate. A light emitting element is electrically connected to the transistor. The substrate includes a first base layer. A first barrier layer is disposed on the first base layer. A second base layer is disposed on the first barrier layer and has a first opening overlapping the transmission region. A second barrier layer is disposed on the second base layer. The first base layer and the second base layer include a transparent material.

### CROSS-REFERENCE TO RELATED APPLICATION

This application claims priority under 35 U.S.C. § 119 to Korean Patent Application No. 10-2024-0166226, filed on Nov. 20, 2024 in the Korean Intellectual Property Office, the disclosure of which is incorporated by reference in its entirety herein.

### 1. TECHNICAL FIELD

The present disclosure relates to a display device, an electronic device, and a method for manufacturing the display device, and more particularly, to a display device having increased transmittance in a transmission region, an electronic device including the same, and a method for manufacturing the display device.

### 2. DISCUSSION OF RELATED ART

A display device may include optical devices, such as sensors and cameras. The optical device may be positioned in a bezel area, such as an area surrounding a screen, of the display device to avoid interference with the screen.

However, as the area occupied by the display area among display devices increases and the bezel is reduced, technology is being developed to position the optical device within the screen.

### SUMMARY

Embodiments of the present disclosure provide a display device, an electronic device and a method of manufacturing a display device having increased light transmittance in a transmission region.

According to an embodiment of the present disclosure, a display device includes a substrate including a pixel region and a transmission region. A transistor is disposed on the pixel region of the substrate. A light emitting element is electrically connected to the transistor. The substrate includes a first base layer. A first barrier layer is disposed on the first base layer. A second base layer is disposed on the first barrier layer and has a first opening overlapping the transmission region. A second barrier layer is disposed on the second base layer. The first base layer and the second base layer include a transparent material.

In an embodiment, a thickness of a region of the first base layer that overlaps the transmission region may be less than a thickness of a region of the first base layer that is spaced apart from the transmission region.

In an embodiment, a thickness of a region of the first base layer that overlaps the transmission region may be in a range of about 1 μm to about 10 μm.

In an embodiment, the thickness of the region of the first base layer that overlaps the transmission region may be in a range of about 1 μm to about 2 μm.

In an embodiment, an entirety of the second base layer may be spaced apart from the transmission region.

In an embodiment, the second barrier layer may have a second opening overlapping the transmission region.

In an embodiment, an entirety of the second barrier layer may be spaced apart from the transmission region.

In an embodiment, the first barrier layer may have a third opening overlapping the transmission region.

In an embodiment, an entirety of the first barrier layer may be spaced apart from the transmission region.

In an embodiment, the light emitting element may further comprise an encapsulation layer disposed on the light emitting element.

In an embodiment, the encapsulation layer includes a first inorganic encapsulation layer, an organic encapsulation layer, and a second inorganic encapsulation layer, and the first inorganic encapsulation layer may cover a side surface of the second base layer.

According to an embodiment of the present disclosure, an electronic device includes a cover window. A housing is coupled with the cover window. A display device is disposed between the cover window and the housing. The display device includes a substrate including a pixel region and a transmission region. A transistor is disposed on the pixel region of the substrate. A light emitting element is electrically connected to the transistor. The substrate includes a first base layer, a first barrier layer disposed on the first base layer, a second base layer disposed on the first barrier layer and having a first opening overlapping the transmission region, and a second barrier layer disposed on the second base layer. The first base layer and the second base layer include a transparent material.

In an embodiment, the electronic device may further comprise an optical device overlapping the transmission region.

In an embodiment, a thickness of a region of the first base layer that overlaps the transmission region may be less than a thickness of a region of the first base layer that is spaced apart from the transmission region.

In an embodiment, the thickness of the region of the first base layer that overlaps the transmission region may be in a range of about 1 μm to about 2 μm.

In an embodiment, the second barrier layer may have a second opening overlapping the transmission region.

In an embodiment, the first barrier layer may have a third opening overlapping the transmission region.

According to an embodiment of the present disclosure, a method for manufacturing a display device includes preparing a glass layer, preparing a substrate including a pixel region and a transmission region on the glass layer, forming a transistor on the substrate, forming a light emitting element electrically connected to the transistor, and removing the glass layer. The forming of the substrate includes forming a first layer on the glass layer, partially etching an area in the first layer overlapping the transmission region, sequentially forming a first inorganic layer, a second layer, and a second inorganic layer on the first layer, and etching regions of the second layer and the second inorganic layer overlapping the transmission region. The first layer and the second layer include a transparent material.

In an embodiment, the etching of regions of the second layer and the second inorganic layer overlapping the transmission region may include forming a first opening overlapping the transmission region in the second layer, and forming a second opening overlapping the transmission region in the second inorganic layer.

In an embodiment, the removing the glass layer may be performed by irradiating a laser onto a rear surface of the glass layer.

According to embodiments, a display device, an electronic device, and a method of manufacturing the display device including a transmission region having increased transmittance may be provided.

### BRIEF DESCRIPTION OF THE DRAWINGS

FIG. 1 is a schematic perspective view illustrating a state of use of a display device according to an embodiment of the present disclosure.

FIG. 2 is an exploded perspective view of a display device according to an embodiment of the present disclosure.

FIG. 3 is a block diagram of a display device according to an embodiment of the present disclosure.

FIG. 4 is a cross-sectional view illustrating a portion of a second display area of FIGS. 1 and 2 in a display device according to an embodiment of the present disclosure.

FIG. 5 is a cross-sectional view illustrating a portion of the second display area of FIGS. 1 and 2 in a display device according to an embodiment of the present disclosure.

FIGS. 6 to 11 are cross-sectional views sequentially showing a manufacturing process of a display device according to embodiments of the present disclosure.

FIGS. 12 to 16 are cross-sectional views sequentially showing a manufacturing process of a display device according to embodiments of the present disclosure.

### DETAILED DESCRIPTION OF EMBODIMENTS

Hereinafter, various embodiments of the present disclosure will be described in detail with reference to the attached drawings so that a person having ordinary skill in the art to which the present disclosure pertains could easily implement the invention. The present disclosure may be embodied in many different forms and is not limited to embodiments described herein.

To facilitate clear explanation of the present disclosure, parts irrelevant to the description are omitted, and the same reference numerals are used for identical or similar components throughout the specification.

In addition, the size and thickness of each component shown in the drawings may be arbitrarily shown for convenience of explanation, so the present disclosure is not necessarily limited to that which is shown. In the drawings, the thickness of layers, films, panels, regions, etc., may be exaggerated for clarity. And in the drawings, for convenience of explanation, the thickness of some layers and areas may be exaggerated.

Also, when it is said that a part, such as a layer, membrane, region, or plate, is “over” or “on” another part, this includes not only cases where it is “directly over” the other part, but also cases where there are other parts in between. In contrast, when a part is referred to as being “directly on” another part, there are no intervening parts present. Also, being “above” or “on” a reference part means being located above or below the reference part, and does not necessarily mean being located “above” or “on” it in the opposite direction of gravity.

Additionally, throughout the specification, whenever a part is said to “include” a component, this does not mean that it excludes other components, but rather that it may include other components, unless otherwise specifically stated.

Additionally, throughout the specification, when reference is made to “in a plan view,” it means when the target part is viewed from above, and when reference is made to “in a cross-section,” it means when the target part is viewed from the side after being vertically cut.

The present disclosure concerns a display device that includes a second display area having a pixel area and a transmission area. An optical device may overlap the transmission region. A first base layer and a second base layer disposed in the second display area may be composed of a transparent material, such as a polymer resin. A thickness of the first base layer in the transmission region may be reduced. The second base layer may have an opening overlapping the transmission region. In some embodiments a second barrier layer disposed on the second base layer may also have an opening overlapping the transmission region.

The substrate including a thin and transparent material in a region overlapping the transmission region of the second display area increases light transmittance in the transmission region. For example, when the thickness of the first base layer in the transmission region is in a range of about 1 μm to about 2 μm, transmittance in the transmission region may be in a range of about 95% to about 98%.

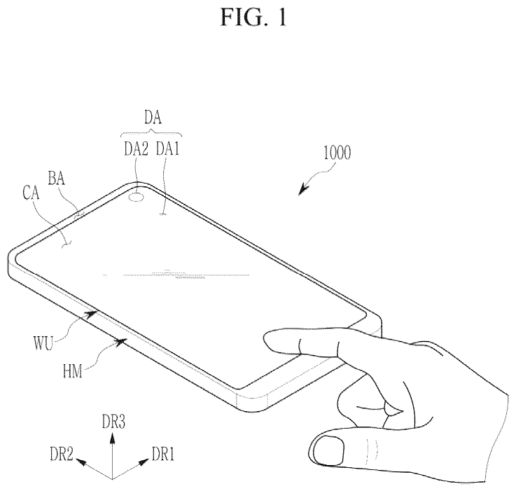

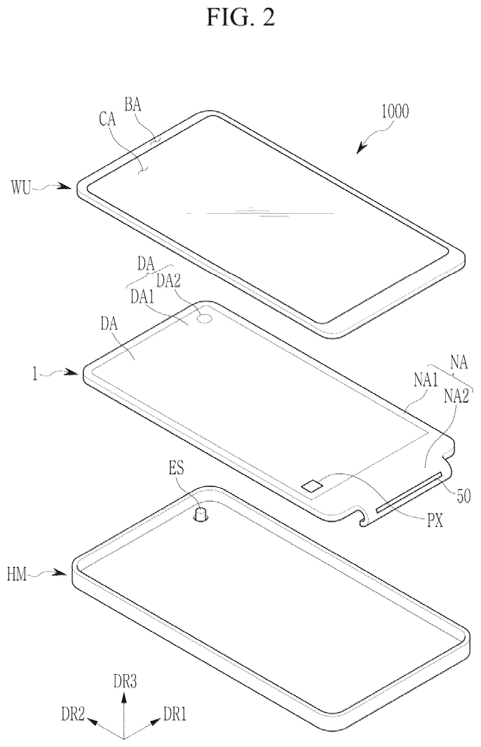

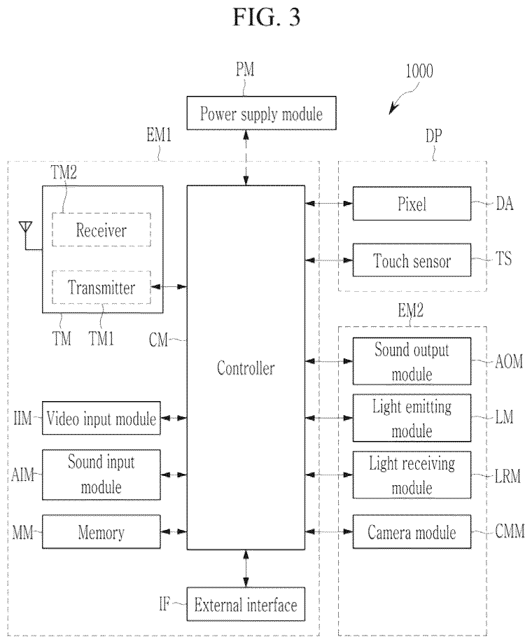

FIG. 1 is a schematic perspective view illustrating a state of use of an electronic device according to an embodiment, FIG. 2 is an exploded perspective view of an electronic device according to an embodiment, and FIG. 3 is a block diagram of an electronic device according to an embodiment.

Referring to FIG. 1, an electronic device 1000 according to an embodiment is a device that displays at least one moving image and/or still image, and may be a mobile phone, a smartphone, a tablet personal computer PC, a mobile communication terminal, an electronic notebook, an electronic book, a portable multimedia player PMP, a navigation device, an ultramobile PC UMPC, and the like, as well as various electronic devices such as a television, a laptop, a monitor, a billboard, and the Internet of Things IOT. Additionally, the electronic device 1000 according to an embodiment may be a wearable device such as a smartwatch, a watch phone, a glasses-type display, and a head mounted display HMD. For convenience of explanation, FIG. 1 illustrates an electronic device 1000 being used as a smartphone. However, embodiments of the present disclosure are not necessarily limited thereto and the electronic device 1000 may be various different small-sized, medium-sized or large-sized electronic devices.

The electronic device 1000 may display an image in a third direction DR3 on a display surface parallel to each of a first direction DR1 and a second direction DR2. In an embodiment, the first to third directions DR1 to DR3 may be perpendicular to each other. However, embodiments of the present disclosure are not necessarily limited thereto and the first to third directions DR1 to DR3 may cross each other at various different angles.

The display surface on which the image is displayed may correspond to the front surface of the electronic device 1000 and may correspond to the front surface of the cover window WU. Images may include still images as well as moving images.

In this embodiment, the front (e.g., an upper) and back (e.g., a lower) surface of each member are defined based on the direction in which the image is displayed. The front and back surfaces are opposite each other in a third direction DR3, and the normal directions of each of the front and back surfaces may be parallel to the third direction DR3. The separation distance in the third direction DR3 between the front and back surfaces may correspond to the thickness of the display panel in the third direction DR3.

An electronic device 1000 according to an embodiment may detect an externally applied user input (see hand in FIG. 1). User input may include various forms of external input, such as parts of the user's body, light, heat, or pressure. In an embodiment shown in FIG. 1, the user's input is depicted as the user's hand being applied to the front. However, embodiments of the present disclosure are not necessarily limited thereto. User input may be provided in various forms, and the electronic device 1000 may also detect user input applied to the side or back.

The electronic device 1000 may include a cover window WU and a housing HM. In an embodiment, the cover window WU and the housing HM may be combined (e.g., coupled with each other) to form the exterior of the electronic device 1000.

The cover window WU may include an insulating panel. For example, in an embodiment the cover window WU may be composed of glass, plastic, or a combination thereof.

The front of the cover window WU may define the front of the electronic device 1000. A transmission area CA of the cover window WU may be an optically transparent area. For example, the transmission area CA may be a region having a visible light transmittance of about 90% or greater.

A blocking area BA may define the shape of the transmission area CA. The blocking area BA is adjacent to the transmission area CA and may surround the transmission area CA (e.g., in a plan view). The blocking area BA may be an area with relatively low light transmittance compared to the transmission area CA. The blocking area BA may include an opaque material that blocks light. The blocking area BA may have a given color. In an embodiment, the blocking area BA may be defined by a bezel layer provided separately from the transparent substrate defining the transmission area CA, or by an ink layer formed by inserting or coloring the transparent substrate.

The housing HM may be combined with the cover window WU. The cover window WU may be positioned on the front of the housing HM. The housing HM may be combined with the cover window WU to provide a predetermined accommodation space.

The housing HM may comprise a material having relatively high stiffness. For example, in an embodiment the housing HM may include a plurality of frames and/or plates made of glass, plastic, or metal, or a combination thereof. The housing HM may reliably protect the components of the electronic device 1000 accommodated in the internal space from external impact.

Referring to FIG. 1 and FIG. 2 below, a display device 1 and an optical element ES (e.g., an optical device) may be accommodated in a predetermined accommodation space provided between the housing HM and the cover window WU.

The display device 1 may include pixels PX that display an image and a driving unit 50, and the pixels PX are located in a display area DA. The display device 1 may include a front surface including the display area DA and a non-display area NA. In an embodiment, the display area DA is an area where an image is displayed and includes the pixels PX. The display area DA may also include an area where a touch sensor is positioned above the pixels PX in the third direction DR3 to detect an external input.

The transmission area CA of the cover window WU may at least partially overlap the display area DA of the display device 1 (e.g., in the third direction DR3). Accordingly, the user may view the image through the transmission area CA or provide external input based on the image. However, embodiments of the present disclosure are not necessarily limited thereto, and the area where the image is displayed and the area where the external input is detected may be separated from each other and may not overlap each other in the third direction DR3).

The non-display area NA of the display device 1 may at least partially overlap the blocking area BA of the cover window WU (e.g., in the third direction DR3). The non-display area NA may be an area covered by the blocking area BA. The non-display area NA is adjacent to the display area DA and may surround at least a portion of the display area DA (e.g., in the plan view). The non-display area NA does not display an image, and driving circuits or driving wiring may be arranged to drive the display area DA. The non-display area NA may include a first peripheral area NA1 located outside the display area DA and a second peripheral area NA2 located outside the display area DA which includes a driving unit 50, a connecting wire, and a bending area. In an embodiment shown in FIG. 2, the first peripheral area NA1 is located on three sides of the display area DA, and the second peripheral area NA2 is located on the remaining one side of the display area DA, such as the lower side in the second direction DR2).

In an embodiment, a portion of the non-display area NA of the display device 1 may be curved. In an embodiment, some of the non-display area NA may face the back of the electronic device 1000, so the blocking area BA visible on the front of the electronic device 1000 may be reduced.

A second display area DA2 may be at least partially surrounded by a first display area DA1 (e.g., in a plan view). Referring to FIG. 2, the second display area DA2 may be an area where an optical element ES (e.g., an optical device) using infrared rays, visible light, or sound is disposed at its lower portion.

The display area DA is formed with a plurality of light emitting diodes and a plurality of pixel circuits that generate and transmit light emitting current to each of the plurality of light emitting diodes. Here, one light emitting diode and one pixel circuit are called a pixel PX. In an embodiment, in the display area DA, one pixel circuit unit and one light emitting diode may be formed on a one-to-one basis.

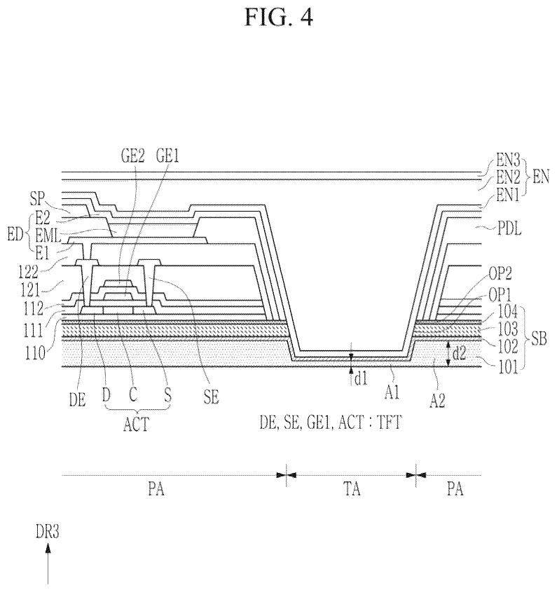

The second display area DA2 may include a transmission region (TA of FIG. 4) through which light and/or sound may pass and a pixel region (PA of FIG. 4) including a plurality of pixels. In an embodiment, the pixel region PA may at least partially surround the transmission region TA (e.g., in a plan view). The transmission region is located between adjacent pixels and is composed of a layer through which light and/or sound may pass. In an embodiment, a layer that is impermeable to light of a certain wavelength (e.g., visible light) may overlap the second display area DA2 (e.g., in the third direction DR3).

The second display area DA2 may include a first component area and a second component area. The number of pixels per unit area (hereinafter also referred to as resolution) of pixels included in the display area DA may be the same as the number of pixels per unit area of pixels included in the first component area. The second component area includes a light transmitting region formed of a transparent layer that allows light to pass through, and the light transmitting region may have a structure in which no conductive layer or semiconductor layer is positioned and does not block light. The number of pixels per unit area of pixels included in the second component area may be less than the number of pixels per unit area of pixels included in the display area DA.

In an embodiment, the driving unit 50 may be mounted in the second peripheral area NA2, and may be mounted on the bending portion or located on either side of the bending portion. In an embodiment, the driving unit 50 may be provided in the form of a chip.

The driving unit 50 is electrically connected to the display area DA and may transmit electrical signals to the pixels. For example, the driving unit 50 may provide data signals to pixels PX arranged in the display area DA. Alternatively, the driving unit 50 may include a touch driving circuit and may be electrically connected to a touch sensor disposed in the display area DA. In an embodiment, the driving unit 50 may be designed to include various circuits in addition to the circuits described above or to provide various electrical signals to the display area DA.

A pad portion may be positioned at the end of the second peripheral area NA2 of the display device 1, and may be electrically connected to a flexible printed circuit board FPCB including a driving chip through the pad portion. Here, the driving chip located on the flexible printed circuit board may include various driving circuits for driving the electronic device 1000 or connectors for power supply. In some embodiments, a rigid printed circuit board PCB may be used instead of a flexible printed circuit board.

The optical element ES (e.g., an optical device) may be disposed at the bottom of the display device 1. The optical element ES may include a first optical element overlapping the first component region and a second optical element overlapping the second component region.

In an embodiment, an optical element ES (e.g., an optical device) may be an electronic element that uses light or sound, and for example, it may be a sensor that receives and uses light, such as an infrared sensor, a sensor that outputs and detects light or sound to measure distance or recognize fingerprints, a small lamp that outputs light, or a speaker that outputs sound. The optical element ES may be at least one of a camera, an infrared camera (IR camera), a dot projector, an IR illuminator, and a time-of-flight sensor (ToF sensor). The optical element ES may additionally include a light detection sensor or a heat detection sensor. The optical element ES may detect an external subject received through the front or provide an audio signal such as a voice to the outside through the front. The optical element ES may include multiple configurations and is not necessarily limited to any one embodiment.

Referring to FIG. 3 below, the electronic device 1000 may include the display device DP, a power supply module PM, a first electronic module EM1, and a second electronic module EM2. The display device 1, the power supply module PM, the first electronic module EM1, and the second electronic module EM2 may be electrically connected to each other.

In FIG. 3, pixels PX and touch sensors TS located in the display area of the display device 1 are illustrated as examples. The display device 1 may include pixels PX and a touch sensor TS. The display device 1 includes pixels PX, which are components that generate images and may be viewed by a user from the outside (e.g., the external environment). Additionally, the touch sensor TS may be located on the upper part (e.g., in the third direction DR3) of the pixel PX and may detect an external input applied from the outside. The touch sensor TS may detect external input provided to the cover window.

The power supply module PM may supply power required for the overall operation of the electronic device 1000. The power supply module PM may include a conventional battery module.

The first electronic module EM1 and the second electronic module EM2 may include various functional modules for operating the electronic device 1000. In an embodiment, the first electronic module EM1 may be mounted directly on a motherboard electrically connected to the display device 1 or may be mounted on a separate substrate and electrically connected to the motherboard via a connector.

In an embodiment, the first electronic module EM1 may include a control module CM, a wireless communication module TM, an image input module IIM, an audio input module AIM, a memory MM, and an external interface IF. In an embodiment, some of the modules may not be mounted on the motherboard, but they may be electrically connected to the motherboard via a flexible printed circuit board connected thereto.

The control module CM may control the overall operation of the electronic device 1000. The control module CM may be a microprocessor. For example, the control module CM may activate or deactivate the display device 1. The control module CM may control other modules, such as the image input module IIM or the audio input module AIM, based on touch signals received from the display device 1.

The wireless communication module TM may transmit/receive wireless signals with other terminals using Bluetooth or Wi-Fi lines. The wireless communication module TM may transmit and receive voice signals using general communication lines. In an embodiment, the wireless communication module TM includes a transmitter TM1 that modulates and transmits a signal to be transmitted, and a receiver TM2 that demodulates a received signal.

The image input module IIM may process an image signal and convert it into image data that may be displayed on the display device 1. The audio input module AIM may receive external audio signals from a microphone in recording mode, voice recognition mode, etc., and convert them into electrical voice data.

The external interface IF may act as an interface to connect to an external charger, wired/wireless data port, card socket (e.g., memory card, SIM/UIM card), etc.

In an embodiment, the second electronic module EM2 may include an audio output module AOM, a light emitting module LM, a light receiving module LRM, and a camera module CMM, at least some of which may be positioned on the back of the display device 1 as an optical element ES as shown in FIG. 2. The optical elements ES (e.g., an optical device) may include the light emitting module LM, the light receiving module LRM, and the camera module CMM. Additionally, in an embodiment the second electronic module EM2 may be mounted directly on the motherboard, mounted on a separate substrate and electrically connected to the display device 1 through a connector, or electrically connected to the first electronic module EM1.

The audio output module AOM may convert audio data received from the wireless communication module TM or audio data stored in the memory MM and output it externally.

The light emitting module LM may generate and output light. In an embodiment, the light emitting module LM may output infrared rays. For example, the light emitting module LM may include LED elements. For example, the light receiving module LRM may detect infrared light. The light receiving module LRM may be activated when infrared light above a certain level is detected. The light receiving module LRM may include a CMOS sensor. After infrared light generated from the light emitting module LM is output, it may be reflected by an external object (e.g., a user's finger or face), and the reflected infrared light may be incident on the light receiving module LRM. The camera module CMM may capture external images.

Below, a cross-section of the second display area will be examined with reference to FIG. 4. FIG. 4 is a cross-sectional view illustrating a portion of the second display area of FIGS. 1 and 2 in a display device according to an embodiment.

The second display area DA2 of FIGS. 1 and 2 may include the pixel region PA and the transmission region TA, as illustrated in FIG. 4. The pixel region PA may contain one or more pixels, and the transmission region TA may not contain any pixels. Since the transmission region TA does not have pixel circuits, light emitting elements, touch electrodes, etc. that block the transmission of light, the transmittance is higher than that of the pixel region PA.

Referring to FIG. 4, the substrate SB may include the pixel region PA and the transmission region TA. In an embodiment, the substrate SB may include a first base layer 101, a first barrier layer 102, a second base layer 103, and a second barrier layer 104.

The first base layer 101 may include a first region A1 overlapping the transmission region TA and a second region A2 spaced apart from the transmission region TA. In an embodiment, a thickness d1 of the first region A1 of the first base layer 101 in the third direction DR3 may be less than a thickness d2 of the second region A2 of the first base layer 101. For example, the thickness d2 of the second region A2 of the first base layer 101 may be about 10 μm, and the thickness d1 of the first region A1 of the first base layer 101 may be in a range of about 1 μm to about 10 μm, such as about 1 μm to about 2 μm.

The first base layer 101 may include a concave portion corresponding to the transmission region TA. The first base layer 101 may have a sunken shape in the portion overlapping the transmission region TA. The first base layer 101 may have a step between the transmission region TA and the pixel region PA.

The first barrier layer 102 may be positioned on (e.g., disposed directly thereon) the first base layer 101. The first barrier layer 102 may be formed to cover the first base layer 101 by overlapping the pixel region PA and the transmission region TA.

The first barrier layer 102 may be positioned along (e.g., directly thereon) an upper surface of the first base layer 101. The first barrier layer 102 may have a concave portion corresponding to the transmission region TA, such as the cross-sectional shape of the first base layer 101 in the transmission region TA. The first barrier layer 102 may have a sunken shape in a portion overlapping the transmission region TA. The first barrier layer 102 may have a step between the transmission region Ta and the pixel region PA.

The second base layer 103 may be positioned on (e.g., disposed directly thereon) the first barrier layer 102. The second base layer 103 may have a first opening OP1 overlapping the transmission region TA. In an embodiment, an entirety of the second base layer 103 may be spaced apart from the transmission region TA (e.g., in a plan view). In an embodiment, a thickness of the second base layer 103 in the third direction DR3 may be in a range of about 5 μm to 7 μm, such as about 5.6 μm.

The second barrier layer 104 may be positioned on (e.g., disposed directly thereon) the second base layer 103. The second barrier layer 104 may have a second opening OP2 overlapping the transmission region TA. In an embodiment, an entirety of the second barrier layer 104 may be spaced apart from the transmission region TA (e.g., in a plan view).

In an embodiment, the first barrier layer 102 and the second barrier layer 104 may each include an inorganic insulating material such as silicon nitride SiNx, silicon oxide SiOx, or silicon oxynitride SiOxNy. The first barrier layer 102 and the second barrier layer 104 may be a single-layer or multi-layer structure including the inorganic insulating material.

In an embodiment, the first base layer 101 and the second base layer 103 may include a polymer resin, such as polyether sulfone, polyarylate, polyetherimide, polyethylene naphthalate, polyethylene terephthalate, polyphenylene sulfide, polyimide, polycarbonate, cellulose triacetate, or cellulose acetate propionate. Additionally, the first base layer 101 and the second base layer 103 may include a transparent polymer resin. Since the first base layer 101 and the second base layer 103 overlapping the transmission region TA include transparent materials, light transmittance in the transmission region TA may be increased.

Since the second base layer 103 and the second barrier layer 104 each have the first opening OP1 and the second opening OP2, light transmittance in the transmission region TA may be increased. Furthermore, since a thickness of the region where the first base layer 101 overlaps the transmission region TA is less than the thickness of remaining portion of the second display area DA2, transmittance in the transmission region TA may be increased. For example, when the thickness in the transmission region TA of the first base layer 101 is in a range of about 1 μm to about 2 μm, transmittance may be in a range of about 95% to about 98%.

Referring to FIG. 4, a buffer layer 110 may be positioned on the pixel region PA of the substrate SB. The buffer layer 110 may flatten the surface of the substrate SB and block the penetration of impurities. In an embodiment, the buffer layer 110 may include an inorganic insulating material such as silicon nitride SiNx, silicon oxide SiOx, or silicon oxynitride SiOxNy. The buffer layer 110 may be a single-layer or multi-layer structure containing the inorganic insulating material.

A semiconductor layer ACT may be positioned on the buffer layer 110 (e.g., disposed directly thereon in the third direction DR3). In an embodiment, the semiconductor layer ACT may include any one of amorphous silicon, polycrystalline silicon, and oxide semiconductor. For example, the semiconductor layer ACT may include low-temperature polysilicon (LTPS) or an oxide semiconductor including at least one of zinc (Zn), indium (In), gallium (Ga), tin (Sn), and mixtures thereof. The semiconductor layer ACT may include a channel region C, a source region S, and a drain region D that are distinguished depending on whether or not they are doped with impurities. The source region S and drain region D may have conductive characteristics corresponding to the conductor.

A first gate insulating layer 111 may be positioned on (e.g., disposed directly thereon) the semiconductor layer ACT. The first gate insulating layer 111 may cover the semiconductor layer ACT. In an embodiment, the first gate insulating layer 111 may include an inorganic insulating material such as silicon nitride SiNx, silicon oxide SiOx, or silicon oxynitride SiOxNy. The first gate insulating layer 111 may be a single-layer or multi-layer structure including the inorganic insulating material.

A gate electrode GE1 may be positioned on the first gate insulating layer 111 (e.g., disposed directly thereon in the third direction DR3). In an embodiment, the gate electrode GE1 may include a metal or metal alloy such as copper (Cu), molybdenum (Mo), aluminum (Al), silver (Ag), chromium (Cr), tantalum (Ta), or titanium (Ti). The gate electrode GE1 may be composed of a single layer or multiple layers. The region overlapping the planar gate electrode GE1 among the semiconductor layers ACT may be the channel region C.

A second gate insulating layer 112 may be positioned on (e.g., disposed directly thereon) the gate electrode GE1. In an embodiment, the second gate insulating layer 112 may include an inorganic insulating material such as silicon nitride SiNx, silicon oxide SiOx, or silicon oxynitride SiOxNy. The second gate insulating layer GI2 may be a single-layer or multi-layer structure containing the inorganic insulating material.

A capacitor electrode GE2 may be positioned on the second gate insulating layer 112 (e.g., disposed directly thereon in the third direction DR3). The capacitor electrode GE2 overlaps the gate electrode GE1 (e.g., in the third direction DR3) and may form a capacitor.

A first insulating layer 121 may be positioned on (e.g., disposed directly thereon) the capacitor electrode GE2. In an embodiment, the first insulating layer IL1 may include an inorganic insulating material such as silicon nitride SiNx, silicon oxide SiOx, or silicon oxynitride SiOxNy. The first insulating layer 121 may be a single-layer or multi-layer structure containing the inorganic insulating material.

The source electrode SE and the drain electrode DE may be positioned on the first insulating layer 121 (e.g., disposed directly thereon in the third direction DR3). The source electrode SE and the drain electrode DE are electrically connected to the source region S and the drain region D of the semiconductor layer ACT, respectively, by openings formed in the first insulating layer 121, the second gate insulating layer 112, and the first gate insulating layer 111. Accordingly, the aforementioned semiconductor layer ACT, gate electrode GE1, source electrode SE, and drain electrode DE form one transistor. In some embodiments, a transistor TFT may include only the source region and the drain region of the semiconductor layer ACT instead of the source electrode SE and the drain electrode DE.

In an embodiment, the source electrode SE and drain electrode DE may include a metal or metal alloy such as aluminum (Al), copper (Cu), silver (Ag), gold (Au), platinum (Pt), palladium (Pd), nickel (Ni), molybdenum (Mo), tungsten (W), titanium (Ti), chromium (Cr), or tantalum (Ta). The source electrode SE and drain electrode DE may be composed of a single layer or multiple layers.

A second insulating layer 122 may be positioned over (e.g., disposed directly thereon) the source electrode SE and the drain electrode DE. The second insulating layer 122 covers the source electrode SE and the drain electrode DE. In an embodiment, the second insulating layer 122 is for planarizing the surface of the substrate SB equipped with the transistor, and may be an organic insulating film, and may include one or more materials selected from the group consisting of polyimide, polyamide, acrylic resin, benzocyclobutene, and phenol resin.

A first electrode E1 may be positioned on the second insulating layer 122 (e.g., disposed directly thereon in the third direction DR3). The first electrode E1 may also be referred to as an anode electrode and may be composed of a single layer including a transparent conductive oxide film or a metal material or multiple layers including them. In an embodiment, the transparent conductive oxide film may include indium tin oxide (ITO), poly-ITO, indium zinc oxide (IZO), indium gallium zinc oxide (IGZO), and indium tin zinc oxide (ITZO). The metal material may include at least one of silver (Ag), molybdenum (Mo), copper (Cu), gold (Au), and aluminum (Al).

In an embodiment, the first electrode E1 may be physically and electrically connected to the drain electrode DE through the opening of the second insulating layer 122. Accordingly, the first electrode E1 may receive an output current to be transmitted from the drain electrode DE to the light emitting layer EML.

A pixel defining layer PDL and a spacer SP may be positioned on (e.g., disposed on) the first electrode E1 and the second insulating layer 122. The pixel defining layer PDL includes a pixel aperture that overlaps at least a portion of the first electrode E1. For example, the pixel aperture may overlap the center of the first electrode E1 and may not overlap the edges (e.g., lateral edges) of the first electrode E1. The pixel defining layer PDL may define the formation location of the light emitting layer EML so that the light emitting layer EML may be positioned on the exposed portion of the upper surface of the first electrode E1.

In an embodiment, each of the pixel defining layer PDL and the spacer SP may be an organic insulating layer including one or more materials selected from the group consisting of polyimide, polyamide, acrylic resin, benzocyclobutene, and phenol resin, and according to an embodiment, the pixel defining layer PDL may be formed as a black pixel defining layer including a black pigment.

The light emitting layer EML may be positioned within a pixel aperture defined by the pixel defining layer PDL. In an embodiment, the light emitting layer EML may include an organic material that emits light, such as red, green, or blue. The light emitting layer EML that emits red, green, or blue light may include a small-molecule or large-molecule organic material. Auxiliary layers such as an electron injection layer, an electron transport layer, a hole transport layer, and a hole injection layer may also be included above and below the light emitting layer EML, and the hole injection layer and the hole transport layer may be positioned (e.g., disposed) below the light emitting layer EML, and the electron transport layer and the electron injection layer may be positioned (e.g., disposed) above the light emitting layer EML. In some embodiments, the light emitting layer EML may include quantum dots comprising semiconductor nanocrystals.

A second electrode E2 may be positioned on (e.g., disposed directly thereon) the pixel defining layer PDL and the light emitting layer EML. The second electrode E2 is also referred to as a cathode electrode and in some embodiments may be formed of a transparent conductive layer including indium tin oxide (ITO), indium zinc oxide (IZO), indium gallium zinc oxide (IGZO), and indium tin zinc oxide (ITZO). Additionally, the second electrode E2 may have a translucent characteristic, in which case it may form a microcavity together with the first electrode E1. According to the microcavity structure, light of a specific wavelength is emitted upwards depending on the spacing and characteristics between the two electrodes, and as a result, red, green or blue light may be displayed. In this embodiment, the first electrode E1 may have reflective characteristics.

The first electrode E1, the light emitting layer EML, and the second electrode E2 may form a light emitting element ED.

An encapsulation layer EN may be positioned on (e.g., disposed directly thereon) the second electrode E2 overlapping the pixel region PA and the transmission region TA. In an embodiment, the encapsulation layer EN may include a first inorganic encapsulation layer EN1, an organic encapsulation layer EN2, and a second inorganic encapsulation layer EN3. The encapsulation layer EN may include at least one inorganic layer and at least one organic layer, and the number of inorganic and organic layers comprising the encapsulation layer EN may be varied.

In an embodiment, the first inorganic encapsulation layer EN1 may be in direct contact with the upper surface and side surface of the first barrier layer 102, the side surface of the second base layer 103, and the side surface of the second barrier layer 104, and may cover the side surfaces of the second base layer 103 and the second barrier layer 104 in the transmission region TA.

The organic encapsulation layer EN2 may be in a form that fills at least a portion of the first opening OP1 and the second opening OP2. According to an embodiment, the organic encapsulation layer EN2 may be in a form that fills at least a portion of the concave portion of the first base layer 101 and the first barrier layer 102.

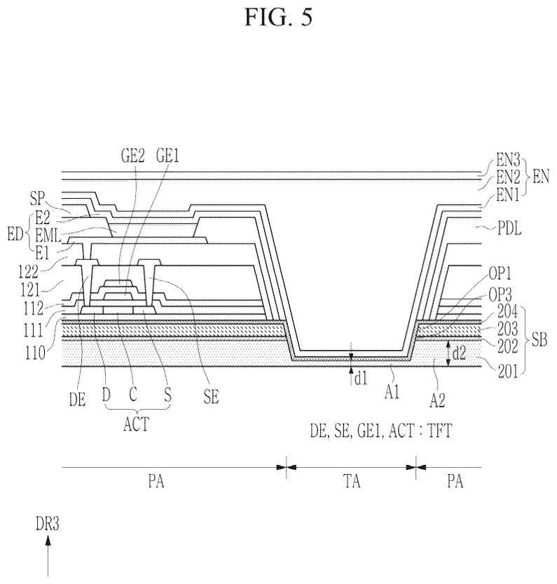

Below, a second display area according to an embodiment will be examined with reference to FIG. 5. FIG. 5 is a cross-sectional view illustrating a portion of the second display area of FIGS. 1 and 2 in a display device according to an embodiment. The embodiment of FIG. 5 differs from the embodiment of FIG. 4 only in the substrate SB, and the remaining configuration is substantially the same, so a description of the overlapping configuration is omitted for economy of explanation.

Referring to FIG. 5, in an embodiment the substrate SB may include a first base layer 201, a first barrier layer 202, a second base layer 203, and a second barrier layer 204.

The first base layer 201 may include a first region A1 overlapping the transmission region TA and a second region A2 spaced apart from the transmission region TA. In an embodiment, a thickness d1 of the first region A1 of the first base layer 201 in the third direction DR3 may be less than a thickness d2 of the second region A2 of the first base layer 201. For example, the thickness d2 of the second region A2 may be about 10 μm, and the thickness d1 of the first region A1 may be in a range of about 1 μm to about 10 μm, such as about 1 μm to about 2 μm.

The first base layer 201 may include a concave portion corresponding to the transmission region TA. The first base layer 201 may have a sunken shape in the portion overlapping the transmission region TA. The first base layer 201 may have a step between the transmission region TA and the pixel region PA.

A first barrier layer 202 may be positioned on the first base layer 201 (e.g., disposed directly thereon in the third direction DR3). The first barrier layer 202 may have a third opening OP3 overlapping the transmission region TA (e.g., in the third direction DR3). In an embodiment, an entirety of the first barrier layer 202 may be spaced apart from the transmission region TA (e.g., in a plan view).

A second base layer 203 may be positioned on the first barrier layer 202 (e.g., disposed directly thereon in the third direction DR3). The second base layer 203 may have the first opening OP1 overlapping the transmission region TA. In an embodiment, an entirety of the second base layer 203 may be spaced apart from the transmission region TA (e.g., in a plan view). In an embodiment, the thickness of the second base layer 203 in the third direction DR3 may be in a range of about 5 μm to about 7 μm, such as about 5.6 μm.

The second barrier layer 204 may be positioned on (e.g., disposed directly thereon) the second base layer 203. The second barrier layer 204 may be formed to cover the first base layer 201 and the second base layer 203 by overlapping the pixel region PA and the transmission region TA.

The second barrier layer 204 may cover an upper surface and a side surface of the second base layer 203, a side surface of the first barrier layer 202, a portion of the side surface of the first base layer 201, and a portion of the upper surface of the first base layer 201. The second barrier layer 204 may cover the concave portion of the first base layer 201. The second barrier layer 204 may be in direct contact with the concave portion of the first base layer 201. The second barrier layer 204 in an embodiment of FIG. 5 may not include the second opening OP2 overlapping the transmission region TA in contrast to the second barrier layer 104 in an embodiment of FIG. 4.

In an embodiment, the first barrier layer 202 and the second barrier layer 204 may each include an inorganic insulating material such as silicon nitride SiNx, silicon oxide SiOx, or silicon oxynitride SiOxNy. The first barrier layer 202 and the second barrier layer 204 may be a single-layer or multi-layer structure including the inorganic insulating material.

In an embodiment, the first base layer 201 and the second base layer 203 may include a polymer resin, such as polyethersulfone, polyarylate, polyetherimide, polyethylene naphthalate, polyethylene terephthalate, polyphenylene sulfide, polyimide, polycarbonate, cellulose triacetate, or cellulose acetate propionate. Additionally, the first base layer 201 and the second base layer 203 may include a transparent polymer resin. Since the first base layer 201 and the second base layer 203 include transparent materials, light transmittance in the transmission region TA may be increased.

Since the second base layer 203 and the first barrier layer 202 each have the first opening OP1 and the third opening OP3, the transmittance in the transmission region TA may be increased. Furthermore, since the thickness of the region where the first base layer 201 overlaps the transmission region TA is less than the thickness of the remaining region, the transmittance of the transmission region TA may be further increased. For example, when the thickness in the transmission region TA of the first base layer 201 is in a range of about 1 μm to about 2 μm, the transmittance may be in a range of about 95% to about 98%.

An encapsulation layer EN overlapping the pixel region PA and the transmission region TA may be positioned on the substrate SB. In an embodiment, the encapsulation layer EN may include the first inorganic encapsulation layer EN1, the organic encapsulation layer EN2, and the second inorganic encapsulation layer EN3.

The first inorganic encapsulation layer EN1 may directly contact the second barrier layer 204 in the transmission region TA.

The organic encapsulation layer EN2 may be in a form that fills at least a portion of the first opening OP1 and the third opening OP3. According to an embodiment, the organic encapsulation layer EN2 may be in a form that fills at least a portion of the concave portion of the first base layer 201.

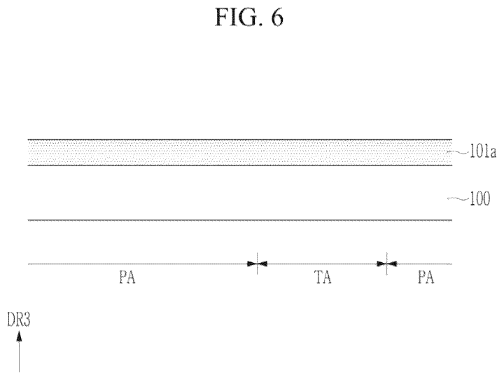

Hereinafter, a method for manufacturing a display device according to an embodiment will be described with reference to FIGS. 6 to 11 together with FIG. 4. FIGS. 6 to 11 are cross-sectional views sequentially showing a manufacturing process of a display device according to embodiments of the present disclosure. Description of the same configuration as the one described above is omitted for economy of explanation.

First, referring to FIG. 6, a glass layer 100 is prepared. A first layer 101a may be formed on (e.g., formed directly thereon in the third direction DR3) an entire surface of a glass layer 100 including the pixel region PA and the transmission region TA. In an embodiment, the first layer 101a may be formed by coating a polymer resin on a glass layer 100 and then curing it. The thickness of the first layer 101a in the third direction DR3 may be about 10 μm.

In an embodiment, the first layer 101a may include a polymer resin, such as polyethersulfone, polyarylate, polyetherimide, polyethylene naphthalate, polyethylene terephthalate, polyphenylene sulfide, polyimide, polycarbonate, cellulose triacetate, or cellulose acetate propionate. Additionally, the first layer 101a may include a transparent material.

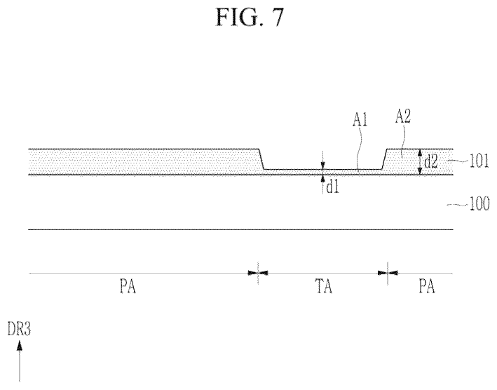

Referring to FIG. 7, a portion of the first layer 101a of FIG. 6 overlapping the transmission region TA may be partially etched in the third direction DR3 to form the first base layer 101. In an embodiment, the first layer 101a of FIG. 6 may be partially removed in the thickness direction by dry etching. The thickness d1 of the first region A1 of the first base layer 101 which overlaps the transmission region TA in the third direction DR3 may be in a range of about 1 μm to about 10 μm, such as about 1 μm to about 2 μm. For example, the thickness d1 of the first region A1 of the first base layer 101 that overlaps the transmission region TA is less than the thickness d2 of the second region A2 of the first base layer 101 spaced apart from the transmission region TA (e.g., in the pixel region PA).

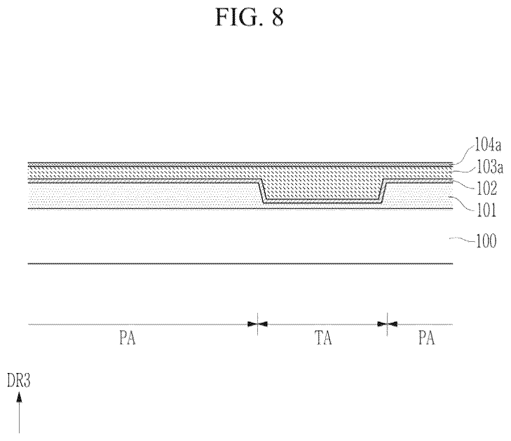

Referring to FIG. 8, a first barrier layer 102, a second layer 103a, and a second inorganic layer 104a may be sequentially formed on the front surface of the first base layer 101. In an embodiment, the first barrier layer 102 may be formed on the first base layer 101 by a chemical vapor deposition (CVD) method, the second layer 103a may be formed by coating a polymer resin on the first barrier layer 102 and then curing it, and the second inorganic layer 104a may be formed on the second layer 103a by a CVD deposition method. In an embodiment, the thickness of the second layer 103a in the third direction DR3 may be in a range of about 5 μm to about 7 μm, such as about 5.6 μm.

In an embodiment, the second layer 103a may include a polymer resin, such as polyethersulfone, polyarylate, polyetherimide, polyethylene naphthalate, polyethylene terephthalate, polyphenylene sulfide, polyimide, polycarbonate, cellulose triacetate, or cellulose acetate propionate. The second layer 103a may include a transparent material.

In an embodiment, the first barrier layer 102 and the second inorganic layer 104a may include inorganic insulating materials such as silicon nitride SiNx, silicon oxide SiOx, and silicon oxynitride SiOxNy.

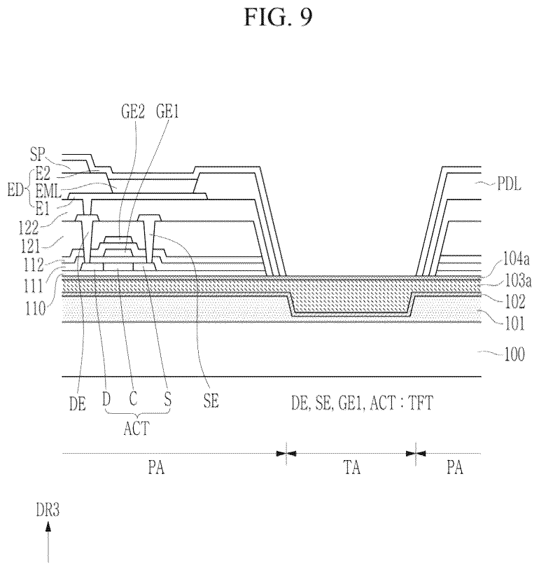

Referring to FIG. 9, the transistor TFT and the light emitting element ED overlapping the pixel region PA may be formed on the second inorganic layer 104a.

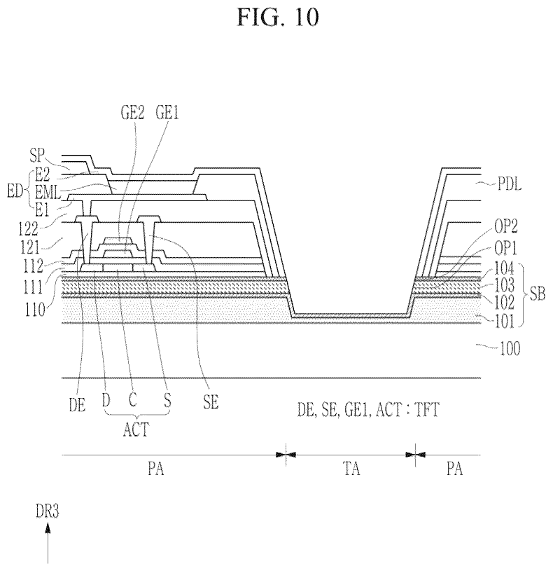

Referring to FIG. 10, in an embodiment the second base layer 103 and the second barrier layer 104 may be formed by etching an area overlapping the transmission region TA in the second layer 103a and the second inorganic layer 104a of FIG. 9, and may be formed by, for example, dry etching. As a result, the second base layer 103 may have the first opening OP1 overlapping the transmission region TA, and the second barrier layer 104 may have the second opening OP2 overlapping the transmission region TA. Entireties of the second base layer 103 and the second barrier layer 104 may be spaced apart from the transmission region TA (e.g., in a plan view).

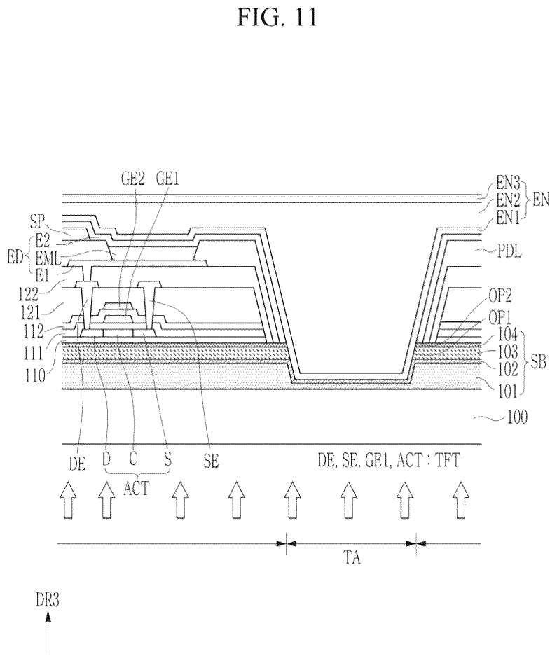

Referring to FIG. 11, the encapsulation layer EN may be formed overlapping the pixel region PA and the transmission region TA on the light emitting element ED. For example, in an embodiment the first inorganic encapsulation layer EN1, the organic encapsulation layer EN2, and the second inorganic encapsulation layer EN3 may be formed sequentially. In an embodiment, the first inorganic encapsulation layer EN1 may be in direct contact with the upper surface of the first barrier layer 102, the side surface of the second base layer 103, and the side surface of the second barrier layer 104 in the transmission region TA.

Referring to FIG. 11 and FIG. 4, a laser is irradiated on the rear surface of the glass layer 100 to remove the glass layer 100, and a display device having a structure similar to that of FIG. 4 may be provided. Since the thickness of the first base layer 101 is greater than or equal to about 1 μm, even if a laser is irradiated on the back (e.g., a rear surface) of the glass layer 100, the first base layer 101 remains.

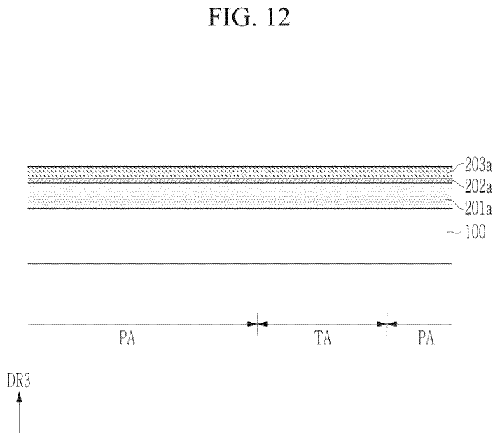

Hereinafter, a method for manufacturing a display device according to an embodiment will be described with reference to FIGS. 12 to 16 together with FIG. 5. FIGS. 12 to 16 are cross-sectional views sequentially illustrating a manufacturing process of a display device according to embodiments of the present disclosure. Description of the same configuration as the aforementioned components is omitted for economy of explanation.

Referring to FIG. 12, a first layer 201a, a first inorganic layer 202a, and a second layer 203a may be sequentially formed on (e.g., in the third direction DR3) the entire surface of the glass layer 100 including the pixel region PA and the transmission region TA. In an embodiment, the first layer 201a may be formed by coating a polymer resin on the glass layer 100 and then curing it, the first inorganic layer 202a may be formed by depositing an inorganic material on the first layer 201a using a CVD deposition method, and the second layer 203a may be formed by coating a polymer resin on the first inorganic layer 202a and then curing it. In an embodiment, the thickness of the first layer 201a in the third direction DR3 may be about 10 μm.

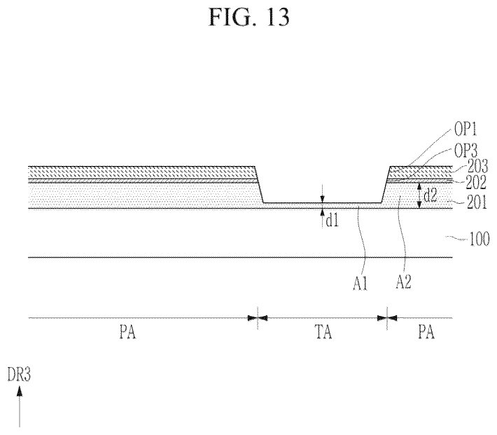

Referring to FIG. 13, an area overlapping the transmission region TA in the second layer 203a, the first inorganic layer 202a, and the first layer 201a of FIG. 12 may be partially etched. For example, in an embodiment shown in FIG. 12, an entire area where the second layer 203a and the first inorganic layer 202a overlap the transmission region TA and a portion of an area where the first layer 201a overlaps the transmission region TA may be removed. By etching the second layer 203a, the second base layer 203 having the first opening OP1 overlapping the transmission region TA may be formed as shown in FIG. 13. By etching the first inorganic layer 202a of FIG. 12, the first barrier layer 202 having the third opening OP3 overlapping the transmission region TA may be formed as shown in FIG. 13. The first layer 201a of FIG. 12 may be partially etched in the third direction DR3 to form the first base layer 201 of FIG. 13. In an embodiment, the thickness d1 of the region A1 of the first base layer 201 which overlaps the transmission region TA may be in a range of about 1 μm to about 10 μm, such as about 1 μm to about 2 μm. For example, the thickness d1 of the region A1 of the first base layer 201 which overlaps the transmission region TA is less than the thickness d2 of the region A2 of the first base layer 201 spaced apart from the transmission region TA (e.g., in a plan view).

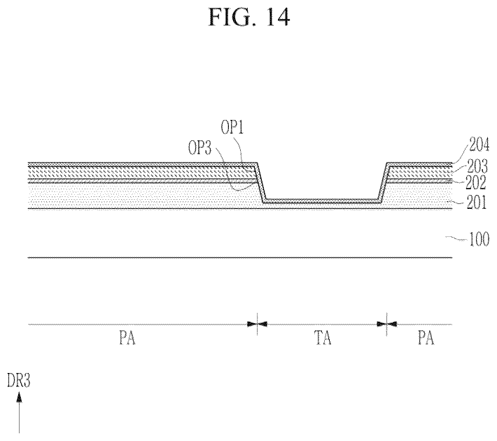

Referring to FIG. 14, the second barrier layer 204 may be formed on (e.g., formed directly thereon) the entire surface of the first base layer 201 and the second base layer 203.

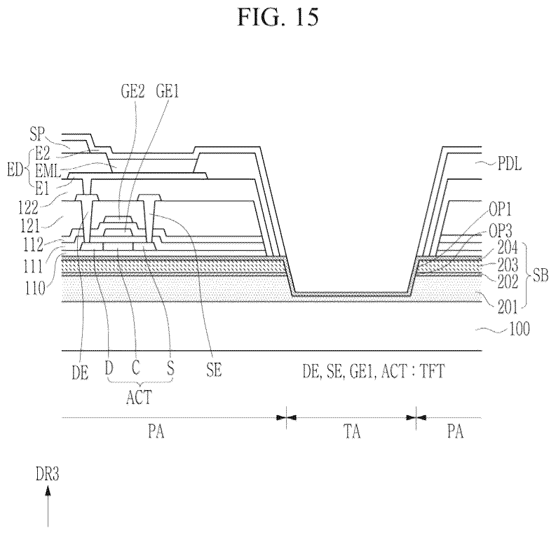

Referring to FIG. 15, the transistor TFT and the light emitting element ED overlapping the pixel region PA may be formed on the second barrier layer 204.

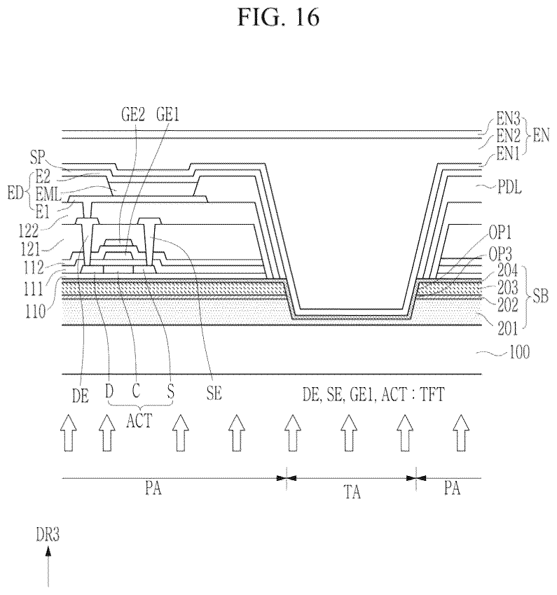

Referring to FIG. 16, the encapsulation layer EN may be formed overlapping the pixel region PA and the transmission region TA on the light emitting element ED. For example, in an embodiment a first inorganic encapsulation layer EN1, an organic encapsulation layer EN2, and a second inorganic encapsulation layer EN3 may be formed sequentially (e.g., in the third direction DR3). The first inorganic encapsulation layer EN1 may directly contact the second barrier layer 204 in the transmission region TA.

Then, referring to FIG. 16 together with FIG. 5, the laser may be irradiated on the rear surface of the glass layer 100 to remove the glass layer 100, thereby providing a display device having the structure shown in FIG. 5. Since the thickness of the first base layer 201 is greater than or equal to about 1 μm, even if the laser is irradiated on the back of the glass layer 100, the first base layer 201 remains.

Embodiments are directed to providing a display device, an electronic device, and a method of manufacturing the display device having increased light transmittance in a transmission region, wherein a substrate includes a thin and transparent material in a region overlapping the transmission region, whereby light transmittance in the transmission region may be increased. In addition, since the thickness of the substrate is greater than or equal to about 1 μm, the substrate may remain even if the laser is irradiated on the lower glass layer during the manufacturing process of the display device.

Although non-limiting embodiments of the present disclosure have been described in detail above, the scope of embodiments of the present disclosure are not limited thereto, and various modifications may be made by those skilled in the art using the basic concepts of the present disclosure also fall within the scope of the present disclosure.

What is claimed is:

1. A display device, comprising:
a substrate comprising a pixel region and a transmission region;
a transistor disposed on the pixel region of the substrate;
a light emitting element electrically connected to the transistor;
the substrate comprises:
a first base layer;
a first barrier layer disposed on the first base layer;
a second base layer disposed on the first barrier layer and having a first opening overlapping the transmission region; and
a second barrier layer disposed on the second base layer,
wherein the first base layer and the second base layer include a transparent material.

2. The display device of claim 1, wherein:
a thickness of a region of the first base layer that overlaps the transmission region is less than a thickness of a region of the first base layer that is spaced apart from the transmission region.

3. The display device of claim 2, wherein:
the thickness of the region of the first base layer that overlaps the transmission region is in a range of about 1 μm to about 10 μm.

4. The display device of claim 3, wherein:
the thickness of the region of the first base layer that overlaps the transmission region is in a range of about 1 μm to about 2 μm.

5. The display device of claim 1, wherein:
an entirety of the second base layer is spaced apart from the transmission region.

6. The display device of claim 1, wherein:
the second barrier layer has a second opening overlapping the transmission region.

7. The display device of claim 6, wherein:
an entirety of the second barrier layer is spaced apart from the transmission region.

8. The display device of claim 1, wherein:
the first barrier layer has a third opening overlapping the transmission region.

9. The display device of claim 8, wherein:
an entirety of the first barrier layer is spaced apart from the transmission region.

10. The display device of claim 1, further comprising:
an encapsulation layer disposed on the light emitting element.

11. The display device of claim 10, wherein:
the encapsulation layer comprises a first inorganic encapsulation layer, an organic encapsulation layer, and a second inorganic encapsulation layer; and
the first inorganic encapsulation layer covers a side surface of the second base layer.

12. An electronic device, comprising:
a cover window;
a housing coupled with the cover window; and
a display device disposed between the cover window and the housing,
the display device comprising:
a substrate including a pixel region and a transmission region;
a transistor disposed on the pixel region of the substrate; and
a light emitting element electrically connected to the transistor,
the substrate comprises
a first base layer;
a first barrier layer disposed on the first base layer;
a second base layer disposed on the first barrier layer and having a first opening overlapping the transmission region; and
a second barrier layer disposed on the second base layer;
wherein the first base layer and the second base layer include a transparent material.

13. The electronic device of claim 12, further comprising:
an optical device overlapping the transmission region.

14. The electronic device of claim 12, wherein:
a thickness of a region of the first base layer that overlaps the transmission region is less than a thickness of a region of the first base layer that is spaced apart from the transmission region.

15. The electronic device of claim 14, wherein:
the thickness of the region of the first base layer that overlaps the transmission region is in a range of about 1 μm to about 2 μm.

16. The electronic device of claim 12, wherein:
the second barrier layer has a second opening overlapping the transmission region.

17. The electronic device of claim 12, wherein:
the first barrier layer has a third opening overlapping the transmission region.

18. A method for manufacturing a display device, comprising:
preparing a glass layer;
preparing a substrate including a pixel region and a transmission region on the glass layer;
forming a transistor on the substrate;
forming a light emitting element electrically connected to the transistor, and
removing the glass layer,
wherein forming the substrate comprises:
forming a first layer on the glass layer;
partially etching a region of the first layer overlapping the transmission region;
sequentially forming a first inorganic layer, a second layer, and a second inorganic layer on the first layer; and
etching regions of the second layer and the second inorganic layer overlapping the transmission region,
wherein the first layer and the second layer include a transparent material.

19. The method for manufacturing the display device of claim 18, wherein:
the etching of regions of the second layer and the second inorganic layer overlapping the transmission region comprises:
forming a first opening in the second layer overlapping the transmission region; and
forming a second opening in the second inorganic layer overlapping the transmission region.

20. The method for manufacturing the display device of claim 18, wherein:
the removing of the glass layer comprises irradiating a laser onto a rear surface of the glass layer.
